(19) United States
(12) Patent Application Publication
(10) Pub. No.: US 2025/0250828 A1
(43) Pub. Date: Aug. 7, 2025

(54) Actuating Device for a Door Handle Assembly of a Vehicle

(71) Applicant: Illinois Tool Works Inc., Glenview, IL (US)

(72) Inventors: Zsolt Wilke, Bad Mergentheim (DE); Andreas Rudolf, Eibelstadt (DE); Erik Dilje, Würzburg (DE); Fritz Göbel, Würzburg (DE)

(21) Appl. No.: 19/015,249

(22) Filed: Jan. 9, 2025

(30) Foreign Application Priority Data
Feb. 5, 2024 (DE) 10 2024 103 086.0

(51) Int. Cl. E05B 85/10; E05B 81/78; H03K 17/975

(52) U.S. Cl. CPC E05B 85/107; E05B 81/78; H03K 17/975; E05Y 2900/531; H03K 2217/9651

(57) ABSTRACT

The disclosure relates to an actuating apparatus (1) for a door handle assembly for actuating, e.g., unlocking and opening, a vehicle door. The actuating apparatus (1) includes a handle part (3), which, when the actuating apparatus (1) is used as intended, at least partially or regionally protrudes from the vehicle door or a vehicle body, in particular from the vehicle outer skin. The handle part (3) includes an actuating surface (5) where a transfer mechanism is integrated in the handle part (3) configured to convert a compressive force, in particular one that is manually applied to the actuating surface (5) of the handle part (3), into a movement that is detectable by a sensor apparatus (6). The sensor apparatus (6) is integrated in the handle part (3). The transfer mechanism includes a carriage-shaped or carriage-like actuating element (7) that is received at least partially or regionally in the handle part (3) and is translationally movable relative to the actuating surface (5) when a compressive force is applied to the actuating surface (5) of the handle part (3).

### RELATED APPLICATION

The present application claims the benefit of German Patent Application No. 10 2024 103 086.0, filed Feb. 5, 2024, titled “Actuating Device for a Door Handle Assembly of a Vehicle,” the contents of which are hereby incorporated by reference.

### BACKGROUND

In the automotive industry, there is an increasing trend of no longer manually opening and closing vehicle doors and flaps of vehicles, in particular outer doors, in the “classical manner.” Rather, the respective opening and closing movements, and in particular the locking and unlocking of doors, are frequently carried out automatically, in particular electrically. An electric motor is typically used for this purpose, which, upon request, drives a mechanism for locking and unlocking the doors and flaps. To generate a signal for opening or closing to such an in particular electromotive actuator or to output it to a corresponding control device, a sensor system, in particular a switch, can be provided, which generates the desired signal by actuation on the part of the operator. Such switches can be configured as push-buttons, which, when pressed in by the operator, generate the aforementioned signal.

In addition to these switches for unlocking a door, pull handles are required in order to be able to pull open the door in question after unlocking. The handle and push-buttons are often difficult to reach with a single hand movement, so that the unlocking and pulling open of doors frequently must be done separately.

Therefore, the problem addressed by the present disclosure is to specify an actuating apparatus for a door handle assembly for actuating a vehicle door, which is configured such that the vehicle door can be unlocked and simultaneously opened in a single movement. Moreover, there is a need for the actuating apparatus to detect an opening request of the operator in a reliable manner.

### SUMMARY

The present disclosure relates generally to an actuating apparatus, substantially as illustrated by and described in connection with at least one of the figures, as set forth more completely in the claims.

### BRIEF DESCRIPTION OF THE DRAWINGS

The foregoing and other objects, features, and advantages of the devices, systems, and methods described herein will be apparent from the following description of particular examples thereof, as illustrated in the accompanying figures; where like or similar reference numbers refer to like or similar structures. The figures are not necessarily to scale, emphasis instead being placed upon illustrating the principles of the devices, systems, and methods described herein.

FIG. 1 illustrates schematically an exemplary embodiment of the actuating apparatus according to the disclosure.

FIG. 2 illustrates schematically and in a sectional view, a region of the handle part of the exemplary embodiment of the actuating apparatus according to the disclosure according to FIG. 1.

FIG. 3 illustrates schematically, a sectional view along the line A in FIG. 1.

FIG. 4 illustrates schematically, a sectional view along the line B in FIG. 1.

### DETAILED DESCRIPTION

References to items in the singular should be understood to include items in the plural, and vice versa, unless explicitly stated otherwise or clear from the text. Grammatical conjunctions are intended to express any and all disjunctive and conjunctive combinations of conjoined clauses, sentences, words, and the like, unless otherwise stated or clear from the context. Recitation of ranges of values herein are not intended to be limiting, referring instead individually to any and all values falling within and/or including the range, unless otherwise indicated herein, and each separate value within such a range is incorporated into the specification as if it were individually recited herein. In the following description, it is understood that terms such as “first,” “second,” “top,” “bottom,” “side,” “front,” “back,” and the like are words of convenience and are not to be construed as limiting terms. For example, while in some examples a first side is located adjacent or near a second side, the terms “first side” and “second side” do not imply any specific order in which the sides are ordered.

The terms “about,” “approximately,” “substantially,” or the like, when accompanying a numerical value, are to be construed as indicating a deviation as would be appreciated by one of ordinary skill in the art to operate satisfactorily for an intended purpose. Ranges of values and/or numeric values are provided herein as examples only, and do not constitute a limitation on the scope of the disclosure. The use of any and all examples, or exemplary language (“e.g.,” “such as,” or the like) provided herein, is intended merely to better illuminate the disclosed examples, and does not pose a limitation on the scope of the disclosure. The terms “e.g.,” and “for example” set off lists of one or more non-limiting examples, instances, or illustrations. No language in the specification should be construed as indicating any unclaimed element as essential to the practice of the disclosed examples.

The term “and/or” means any one or more of the items in the list joined by “and/or.” As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y, and/or z” means “one or more of x, y, and z.”

Therefore, the problem addressed by the present disclosure is to specify an actuating apparatus for a door handle assembly for actuating a vehicle door, which is configured such that the vehicle door can be unlocked and simultaneously opened in a single movement. Moreover, there is a need for the actuating apparatus to detect an opening request of the operator in a reliable manner.

The problem underlying the disclosure is solved in particular by an actuating apparatus, wherein advantageous further developments of the actuating apparatus according to the disclosure are specified in the dependent claims.

Accordingly, the disclosure relates in particular to an actuating apparatus for a door handle assembly for actuating, in particular unlocking and/or opening, a vehicle door, in particular a vehicle outer door. The actuating apparatus comprises a handle part, which, when the actuating apparatus is used as intended, at least partially or regionally, protrudes from the vehicle door or the vehicle body, and in particular from the vehicle outer skin.

Furthermore, it is provided that the handle part comprises an actuating surface.

According to the disclosure, it is provided in particular that, at least partially or regionally, a transfer mechanism is integrated in the handle part, which is configured to convert a compressive force applied, in particular manually, to the actuating surface of the handle part into a movement that is detectable by a sensor apparatus, which is integrated in particular in the handle part.

For this purpose, the transfer mechanism preferably comprises a carriage-shaped or carriage-like actuating element, which is translationally movable relative to the actuating surface upon application of a compressive force to the actuating surface, which is at least partially or regionally received in the handle part.

By providing such a transfer mechanism, which is at least partially or regionally integrated in the handle part, it is possible to reliably detect a compressive force applied to the actuating surface with the aid of the sensor apparatus in an easily implemented yet effective manner, and to subsequently generate a corresponding unlocking and/or opening signal. In particular, the transfer mechanism is configured such that it does not matter in which region of the actuating surface of the handle part the operator actually applies a compressive force. Thus, even with a relatively large actuating surface, it is always ensured that a corresponding opening request by the operator is detected with the help of the sensor apparatus, which is integrated in the handle part.

In addition, with the solution according to the disclosure, there is a broad freedom of design for the realization of the handle part. The handle part can have different shapes, and in particular a flat design of the handle part is contemplated.

By allowing the transfer mechanism together with the sensors to be fully integrated in the handle part, additional design space is saved.

According to a preferred implementation of the actuating apparatus according to the disclosure, it is provided that the carriage-shaped or carriage-like actuating element is movable between a first position and a second position within the handle part, wherein the first position is a resting position of the carriage-shaped or carriage-like actuating element, which the carriage-shaped or carriage-like actuating element assumes when no compressive force is applied to the actuating surface of the handle part. In the second position of the carriage-shaped or carriage-like actuating element, on the other hand, the carriage-shaped or carriage-like actuating element is at least partially or regionally within a detection range of the sensor apparatus.

This design is characterized by its particularly simple construction. In particular, the carriage-shaped or carriage-like actuating element can be relatively flat, so that the entire transfer mechanism can be easily integrated in the handle part of the actuating apparatus without any necessary design changes.

Preferably, a biasing element, in particular in the form of a spring, is associated with the carriage-shaped or carriage-like actuating element in order to bias the carriage-shaped or carriage-like actuating element into its first position, i.e., its resting position.

In this context, in order to spare additional components, it is contemplated that the biasing element is configured as an elastic and in particular spring-elastic region of the carriage-shaped or carriage-like actuating element.

In this context, it is contemplated in particular that the elastic and in particular spring-elastic region of the carriage-shaped or carriage-like actuating element is formed at or in a first end region of the carriage-shaped or carriage-like actuating element, wherein an end region of the elastic and in particular spring-elastic region facing away from a main body of the carriage-shaped or carriage-like actuating element is preferably releasably connected to a housing structure of the handle part.

In a further development of the last mentioned embodiment, it is provided that, in the second position of the carriage-shaped or carriage-like actuating element, a second end region of the carriage-shaped or carriage-like actuating element opposite the first end region of the carriage-shaped or carriage-like actuating element is located at least partially or regionally within the detection region of the sensor apparatus.

In order to ensure a defined and in particular guided translational movement of the carriage-shaped or carriage-like actuating element at least partially or regionally integrated in the handle part, it is provided according to design variants of the actuating apparatus according to the disclosure that the transfer mechanism comprises a straight-line guide (linear guide) configured at least partially or regionally in the handle part, with the aid of which the carriage-shaped or carriage-like actuating element is translationally movable. The straight-line guide is preferably realized by corresponding guiding surfaces connected to the housing structure of the handle part or formed by the housing structure of the handle part.

Preferably, the transfer mechanism comprises at least one stop associated with the carriage-shaped or carriage-like actuating element for limiting a translational movement that can be performed by the carriage-shaped or carriage-like actuating element.

Here, too, it is expedient that the at least one stop associated with the carriage-shaped or carriage-like actuating element is integrally formed with a housing structure of the handle part.

According to preferred implementations of the actuating apparatus according to the disclosure, it is provided that the transfer mechanism is configured to convert a compressive force applied to the actuating surface of the handle part into a translational movement of the carriage-shaped or carriage-like actuating element, according to the principle of the inclined plane.

According to design variants of the actuating apparatus according to the disclosure, it is provided that at least one wedge-shaped or ramp-shaped protrusion is formed on the rear side of the actuating surface of the handle part, which is received at least partially or regionally in particular in a receiving region configured in the main body of the carriage-shaped or carriage-like actuating element.

The at least one wedge-shaped or ramp-shaped protrusion of the actuating surface of the handle part and/or the receiving region of the carriage-shaped or carriage-like actuating element associated with the wedge-shaped or ramp-shaped protrusion is/are in particular configured in such a way that, when a compressive force is applied to the actuating surface, the wedge-shaped or ramp-shaped protrusion of the actuating surface of the handle part is moved further into the receiving region, as a result of which the carriage-shaped or carriage-like actuating element is pushed in the direction of the translational movement that can be performed by the carriage-shaped or carriage-like actuating element.

Of course, however, a kinematic reversal is also conceivable, in which the receiving region of the carriage-shaped or carriage-like actuating element has a wedge-shaped or ramp-shaped surface, against which a protrusion of the actuating surface of the handle part strikes, and a translational movement of the carriage-shaped or carriage-like actuating element is generated upon application of a compressive force on the actuating surface.

Preferably, a plurality of wedge-shaped or ramp-shaped protrusions are formed on the rear side of the actuating surface of the handle part, which interact with corresponding receiving regions configured in particular in a main body of the carriage-shaped or carriage-like actuating element to carry out the transfer mechanism as insensitively as possible with regard to the region of the actuating surface of the handle part in which a compressive force is ultimately applied by the operator.

It is particularly preferred that the transfer mechanism is configured to move the carriage-shaped or carriage-like actuating element in a translational manner relative to the actuating surface only when a critical compressive force is reached or exceeded, in particular a compressive force that is predefined or definable and is applied to the actuating surface. In this way, it is effectively prevented that the transfer mechanism already responds to a low compressive force. This is the case, for example, when the operator merely touches the actuating surface, but a compressive force is not applied to the actuating surface due to an actual opening request by the operator.

In this context, it is further preferred that the transfer mechanism comprises a pressure point that is perceptible to the operator acoustically and/or in particular in a tactile manner via the actuating surface of the handle part upon reaching or exceeding the critical compressive force applied to the actuating surface.

Various approaches are considered for the realization of this further development.

On the one hand, it is conceivable that, in order to implement the pressure, point that is perceptible acoustically and/or in a tactile manner via the actuating surface, the transfer mechanism comprises a snap-action spring, being configured in particular as a snap-action frog.

In a further development of this design variant, it is conceivable that the snap-action spring is configured as a contact-transmitting component with respect to the sensor apparatus, in particular as a snap dome.

Alternatively or in addition to the use of a snap-action spring, which is configured in particular as a snap-action frog, it is contemplated that the carriage-shaped or carriage-like actuating element comprises at least one spring-elastically mounted region, which, in the first position of the carriage-shaped or carriage-like actuating element, strikes against a protrusion, being in particular connected to a housing structure of the handle part, wherein, when the critical compressive force applied to the actuating surface is reached or exceeded, an engagement between the at least one spring-elastically mounted region and the protrusion is lifted.

In this context, it is contemplated in particular that the at least one spring-elastically mounted region comprises an arm region extending in the direction of the translational movement that can be performed by the carriage-shaped or carriage-like actuating element, wherein, at a first end region of the arm region, an in particular wedge-shaped stop surface, in particular an incline, is formed, which in the first position of the carriage-shaped or carriage-like actuating element, strikes against the protrusion of the housing structure of the handle part, wherein a second end region of the arm region opposite the first end region of the arm region is connected to a main body of the carriage-shaped or carriage-like actuating element.

According to implementations of the actuating apparatus according to the disclosure, the sensor apparatus, which is preferably integrated in the handle part, is configured in the form of a switch, in particular a microswitch. Alternatively, however, it is also conceivable that the sensor apparatus is designed with a switch, in particular a microswitch. Of course, however, other embodiments are also considered for the sensor apparatus, which is in particular integrated in the handle part.

According to design variants of the actuating apparatus according to the disclosure, it is provided that the actuating apparatus comprises a mounting structure, which, when the actuating apparatus is used as intended, is at least partially or regionally attached to the vehicle door, or received within the vehicle door.

A housing structure of the handle part should preferably be connected to the mounting structure, and preferably integrally formed with the mounting structure.

In particular, it is contemplated that the mounting structure of the actuating apparatus as well as the housing structure of the handle part are formed together in the context of a plastic injection-molding process.

In implementations of the actuating apparatus according to the disclosure, it is provided that, when the actuating apparatus is used as intended, the handle part protrudes at least partially or regionally from the vehicle door or from the vehicle body, such that the handle part can be at least partially or regionally manually grasped. Preferably, the actuating surface of the handle part is configured on or in a surface of the handle part facing the vehicle door or the vehicle body.

To form the actuating surface, it is contemplated that at least the surface of the handle part facing the vehicle body or the vehicle door is at least partially or regionally, and preferably entirely, formed by a cover, wherein the actuating surface of the handle part is formed by a spring-elastic region formed in the cover.

The disclosure further relates to an actuating apparatus as specified in the parallel claim 22. It is provided that the actuating apparatus further comprises a capacitive proximity switch.

The further aspect of the disclosure is in particular wherein the capacitive proximity switch comprises at least one capacitive sensor having at least one measuring electrode, wherein the at least one measuring electrode is at least partially or regionally formed by a surface of the handle part printed with an electrically conductive ink or layer, in particular in the course of a pad printing process.

In this way, it is possible for the electronics of the capacitive proximity switch to be integrated, for example in the housing structure of the actuating apparatus, wherein the measurement field of the capacitive proximity switch or the at least one capacitive sensor can still be expanded as desired.

Finally, the disclosure relates to a door handle assembly for actuating, in particular unlocking and/or opening, a vehicle door, in particular a vehicle outer door having an actuating apparatus of the aforementioned type according to the disclosure.

Furthermore, the disclosure relates to a vehicle door, in particular a vehicle outer door, having such a door handle assembly.

It is provided in particular that the vehicle door and/or the door handle assembly and/or the actuating apparatus form a handle region having a longitudinal direction for coming into contact with a plurality of fingers of a operator along the longitudinal direction, wherein the expansion of the handle region in the longitudinal direction is at least 2 cm, wherein the actuating surface forms a surface of the handle region and is arranged over at least 50% of the handle region in the longitudinal direction.

The exemplary embodiment of the actuating apparatus 1 according to the disclosure as shown in the drawings is an actuating apparatus 1 for a door handle assembly for actuating, and in particular unlocking and opening, a vehicle door, in particular a vehicle outer door.

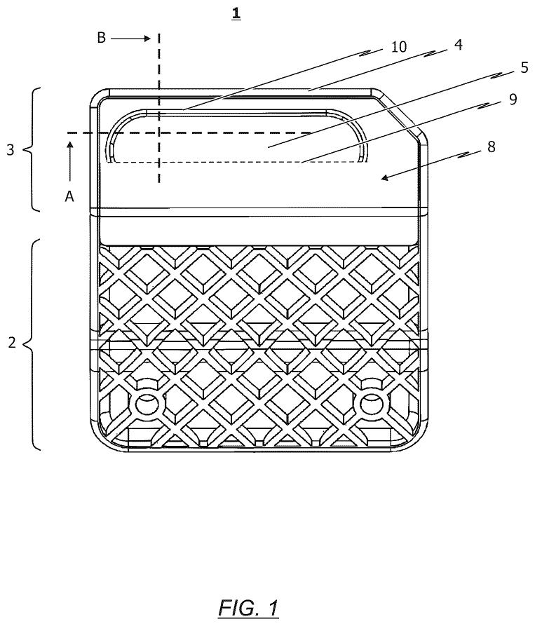

As indicated schematically in FIG. 1, the actuating apparatus 1 comprises a mounting structure 2, preferably formed from plastic, which, when the actuating apparatus 1 is used as intended, is attached at least partially or regionally to a vehicle door (not shown in the drawings) or received within a vehicle door.

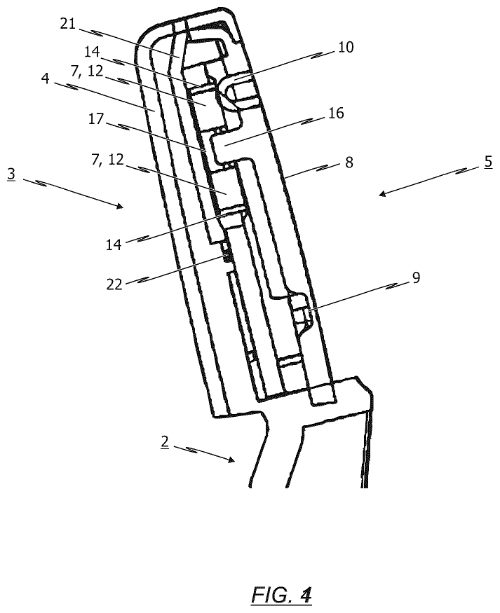

In addition, the actuating apparatus 1 comprises a handle part 3, which, when the actuating apparatus 1 is used as intended, at least partially or regionally, protrudes from the vehicle door or the vehicle body, and in particular from the vehicle outer skin. The latter can be seen in particular from the sectional view according to FIG. 4.

The handle part 3 comprises a housing structure 4, which is preferably formed from plastic. The housing structure 4 of the handle part 3 is integrally connected to the mounting structure 2 of the actuating apparatus 1. Here, it is expedient that both the housing structure 4 of the handle part 3 and the mounting structure 2 of the actuating apparatus 1 are formed together as part of a spray-molding process.

The handle part 3 further comprises an actuating surface 5.

When the actuating apparatus 1 is used as intended, the handle part 3 protrudes at least partially or regionally from the vehicle door or the vehicle body/vehicle outer skin such that the handle part 3 can be manually grasped at least partially or regionally (cf. FIG. 4).

In particular, it is provided that the actuating surface 5 of the handle part 3 is configured on or in a surface of the handle part 3 facing the vehicle door or the vehicle body.

The overall view according to FIG. 1, and in particular the sectional view according to FIG. 4, show that the surface of the handle part 3 facing the vehicle body or the vehicle door is preferably completely formed by a cover 8. The actuating surface 5 is formed by an elastic region configured in the cover 8.

For this purpose, as indicated in FIG. 4, an articulated or hinged region 9 is configured in the rear side of the cover 8. The articulated or hinged region 9 is in particular formed by a groove-shaped recess.

Furthermore, a groove-shaped elastic region 10 is formed opposite the articulated or hinged region 9, such that the articulated or hinged region 9 and the groove-shaped elastic region 10 form the actuating surface 5 of the cover 8.

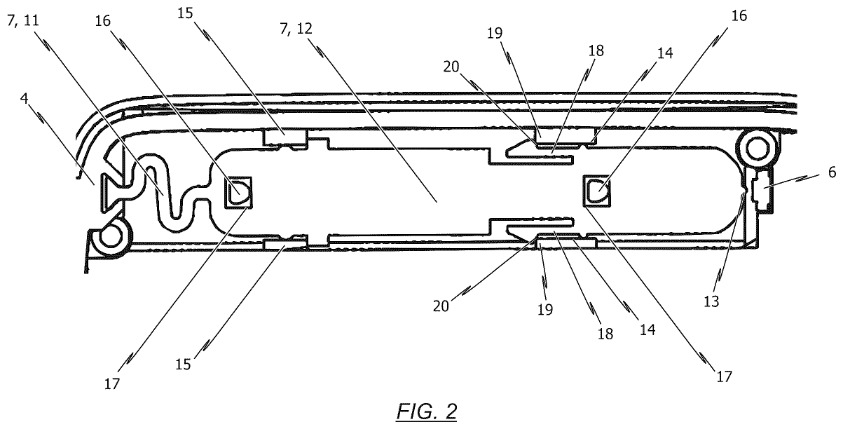

From the sectional view in FIG. 2, it can be seen that, at least partially or regionally, a transfer mechanism is integrated in the handle part 3, which is configured to convert a compressive force applied, in particular manually, to the actuating surface 5 of the handle part 3 into a movement that is detectable by a sensor apparatus 6, which is integrated in particular in the handle part 3.

In the exemplary embodiment shown in the drawings, a microswitch is used as the sensor apparatus 6 integrated in the handle part 3.

To convert a compressive force applied to the actuating surface 5 of the handle part 3 into the movement that is detectable by the sensor apparatus 6, a carriage-shaped or carriage-like actuating element 7 is received in the handle part 3, which is translationally movable relative to the actuating surface 5 (and relative to the housing structure 4 of the handle part 3) upon application of a compressive force to the actuating surface 5 of the handle part 3.

Specifically, the carriage-shaped or carriage-like actuating element 7 is movable between the first position shown in FIG. 2 and a second position (not shown in the drawings). The first position of the carriage-shaped or carriage-like actuating element 7 is a resting position of the actuating element 7, which the carriage-shaped or carriage-like actuating element 7 assumes when no compressive force is applied to the actuating surface 5 of the handle part 3.

By contrast, the carriage-shaped or carriage-like actuating element 7 is at least partially or regionally in the second position of the carriage-shaped or carriage-like actuating element 7 in a detection range of the sensor apparatus 6.

In other words, in the second position of the carriage-shaped or carriage-like actuating element 7, an actuating protrusion 13 of the actuating element 7, which is configured at an end region of the actuating element 7, strikes against the microswitch serving as the sensor apparatus 6, so that a corresponding opening signal indicative of the opening request of the operator is or can be generated.

The sectional view according to FIG. 2 further shows that a biasing element is associated with the carriage-shaped or carriage-like actuating element 7 in order to bias the carriage-shaped or carriage-like actuating element 7 into its first position (resting position).

Although it is generally conceivable that a corresponding spring is used as a biasing element, in the exemplary embodiment of the actuating apparatus 1 according to the disclosure as shown in the drawings, it is provided that the biasing element is configured as an elastic and in particular spring-elastic region 11 of the carriage-shaped or carriage-like actuating element 7.

Specifically, in the exemplary embodiment of the actuating apparatus 1 according to the disclosure as shown in the drawings, it is provided that the elastic and in particular spring-elastic region 11 of the carriage-shaped or carriage-like actuating element 7 is formed at or in a first end region of the carriage-shaped or carriage-like actuating element 7, wherein an end region of the elastic and in particular spring-elastic region 11 facing away from a main body 12 of the carriage-shaped or carriage-like actuating element 7 is preferably releasably connected to the housing structure 4 of the handle part 3.

In the second position of the carriage-shaped or carriage-like actuating element 7, a second end region of the carriage-shaped or carriage-like actuating element 7 opposite the first end region of the carriage-shaped or carriage-like actuating element 7, and in particular the aforementioned actuating protrusion 13 of the actuating element 7 is located at least partially or regionally within the detection region of the sensor apparatus 6, which is configured in particular as a microswitch.

The sectional view in FIG. 2 further shows that the transfer mechanism of the exemplary embodiment of the actuating apparatus 1 according to the disclosure comprises a straight-line guide 14, which is configured at least partially or regionally in the handle part 3, with the help of which the carriage-shaped or carriage-like actuating element 7 is translationally movable.

It can also be seen from the sectional view according to FIG. 2 that the transfer mechanism comprises two mutually opposed stops 15, which are associated with the carriage-shaped or carriage-like actuating element 7. The stops 15 serve to establish the first position of the carriage-shaped or carriage-like actuating element 7 and, in particular, to limit the translational movement that can be performed by the carriage-shaped or carriage-like actuating element 7 towards the first position.

In particular, it is provided that the stops 15 associated with the carriage-shaped or carriage-like operating element 7 are integrally formed with the housing structure 4 of the handle part 3.

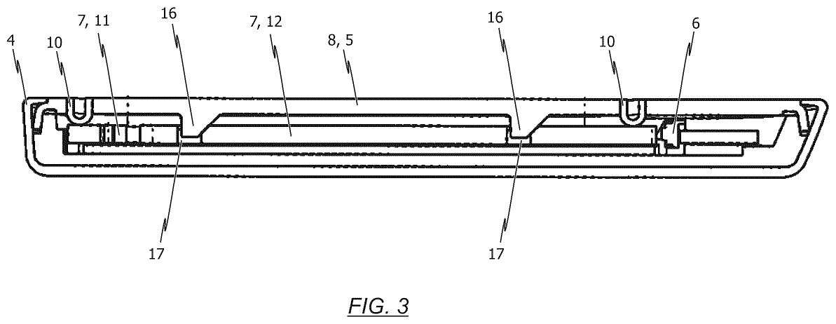

The sectional view according to FIG. 3 shows that the transfer mechanism of the exemplary embodiment of the actuating apparatus 1 according to the disclosure is configured to convert a compressive force applied to the actuating surface 5 of the handle part 3 into a translational movement of the carriage-shaped or carriage-like actuating element 7, according to the principle of the inclined plane.

Specifically, in the exemplary embodiment of the actuating apparatus 1 according to the disclosure as shown in the drawings, it is provided that a plurality of wedge-shaped or ramp-shaped protrusions 16 are formed overall on the rear side of the actuating surface 5 of the handle part 3, which are received at least partially or regionally in a correspondingly associated receiving region 17 configured in the main body 12 of the carriage-shaped or carriage-like actuating element 7.

The wedge-shaped or ramp-shaped protrusions 16 of the actuating surface 5 of the handle part 3 and/or the correspondingly associated receiving regions of the main body 12 of the carriage-shaped or carriage-like actuating element 7 are configured such that, upon application of a compressive force to the actuating surface 5 of the handle part 3, the wedge-shaped or ramp-shaped protrusions 16 are moved further into the corresponding receiving regions 17 of the main body 12 of the carriage-shaped or carriage-like actuating element 7, as a result of which the carriage-shaped or carriage-like actuating element 7 is pushed in the direction of the translational movement that can be performed by the carriage-shaped or carriage-like actuating element 7.

The exemplary embodiment of the actuating apparatus 1 according to the present disclosure, as shown in the accompanying drawings, is also characterized in particular in that the transfer mechanism of the actuating apparatus 1 is configured to translationally move the carriage-shaped or carriage-like actuating element 7 relative to the actuating surface 5 or relative to the base body of the handle part 3 only when a critical compressive force or reached or exceeded, in particular a compressive force that is predefined or definable and is applied to the actuating surface 5 of the handle part 3.

In this context, it is further provided that the transfer mechanism comprises a pressure point that is perceptible to the operator of the actuating apparatus 1 acoustically and/or in a tactile manner via the actuating surface 5 upon reaching or exceeding the critical compressive force applied to the actuating surface 5 of the handle part 3.

In principle, it is conceivable in this regard that, in order to implement the pressure point that is perceptible to the operator acoustically and/or in a tactile manner via the actuating surface 5 of the handle part 3, the transfer mechanism comprises a snap-action spring, being configured in particular as a snap-action frog. It is further contemplated in this context that the snap-action spring is configured as a contact-transmitting component with respect to the sensor apparatus 6 (in relation to the microswitch), in particular as a snap dome.

However, in the design variant of the actuating apparatus 1 according to the disclosure as shown schematically in the drawings, a different realization of the pressure point that is perceptible to the operator acoustically and/or in a tactile manner via the actuating surface 5 of the handle part 3 is used.

Specifically, in the design variant as shown in the drawings (see in particular FIG. 2), it is provided that the carriage-shaped or carriage-like actuating element 7 comprises at least one spring-elastic region 18 which, in the first position of the carriage-shaped or carriage-like actuating element 7, strikes against a protrusion 19 connected in particular to the housing structure 4 of the handle part 3. When the critical compressive force applied to the actuating surface 5 of the handle part 3 is reached or exceeded, on the other hand, the engagement between the spring-elastic region 18 and the protrusion 19 is lifted.

In the design variant of the actuating apparatus 1 according to the disclosure as shown in the drawings, a total of two opposing spring-elastically mounted regions 18 are used. Each spring-elastically mounted region 18 has an arm region that extends in the direction of the translational movement that can be performed by the carriage-shaped or carriage-like actuating element 7. At a first end region of each arm region, an in particular wedge-shaped stop surface 20, in particular an incline, is formed, which, in the first position of the carriage-shaped or carriage-like actuating element 7, strikes against the aforementioned protrusion 19 of the housing structure 4 of the handle part 3. A second end region of the arm region of each spring-elastically mounted region 18 opposite the first end region of the arm region is connected to the main body 12 of the carriage-shaped or carriage-like actuating element 7.

As can be seen from the sectional view in FIG. 4, it is contemplated that the housing structure 4 of the handle part 3 of the actuating apparatus 1 is formed at least regionally from a transparent material 21, in particular a plastic material. It is further provided that a light source (LED 22) is received in the handle part 3 and is activated, for example, when a capacitive proximity sensor is used in order to detect that a hand of the operator is approaching the actuating apparatus 1, and in particular the grip region of the actuating apparatus 1.

Although not shown in the drawings, is it contemplated in this context that the actuating apparatus 1 comprises a corresponding capacitive proximity switch, which comprises at least one capacitive sensor having at least one measuring electrode, wherein the at least one measuring electrode is formed at least partially or regionally by a surface of the handle part 3, which is printed with an electrically conductive ink/layer, in particular in the course of a pad printing process.

While the present method and/or system has been described with reference to certain implementations, it will be understood by those skilled in the art that various changes may be made, and equivalents may be substituted without departing from the scope of the present method and/or system. In addition, many modifications may be made to adapt a particular situation or material to the teachings of the present disclosure without departing from its scope. For example, block and/or components of disclosed examples may be combined, divided, re-arranged, and/or otherwise modified. Therefore, the present method and/or system are not limited to the particular implementations disclosed. Instead, the present method and/or system will include all implementations falling within the scope of the appended claims, both literally and under the doctrine of equivalents.

### LIST OF REFERENCE NUMBERS

1 Actuating apparatus
2 Mounting structure
3 Handle part
4 Housing structure of the handle part
5 Actuating surface of the handle part
6 Sensor apparatus/microswitch
7 Carriage-shaped or carriage-like actuating element
8 Cover
9 Hinge region of the cover
10 Elastic region of the cover
11 Biasing element/elastic region of the carriage-shaped actuating element
12 Main body of carriage-shaped or carriage-like actuating element
13 Actuating protrusion
14 Straight-line guide/guiding surface
15 Stop
16 Wedge-shaped or ramp-shaped protrusion
17 Receiving region
18 Spring-elastically mounted region
19 Protrusion
20 Wedge-shaped stop surface
21 Transparent region
22 Light source/LED

What is claimed is:

1. An actuating apparatus (1) for a door handle assembly for unlocking and opening a vehicle door, the actuating apparatus (1) comprising:
a handle part (3), which, when the actuating apparatus (1) is used as intended, at least partially or regionally protrudes from the vehicle door, wherein the handle part (3) comprises an actuating surface (5); and
a transfer mechanism at least partially or regionally integrated in the handle part (3) configured to convert a compressive force applied to the actuating surface (5) of the handle part (3) into a movement that is detectable by a sensor apparatus (6) that is integrated in the handle part (3),
wherein the transfer mechanism comprises a carriage-shaped or carriage-like actuating element (7) that is received at least partially or regionally in the handle part (3) and is translationally movable relative to the actuating surface (5) when a compressive force is applied to the actuating surface (5) of the handle part (3).

2. The actuating apparatus (1) according to claim 1,
wherein the carriage-shaped or carriage-like actuating element (7) is movable between a first position and a second position,
wherein the first position is a resting position of the carriage-shaped or carriage-like actuating element (7) which the carriage-shaped or carriage-like actuating element (7) assumes when no compressive force is applied to the actuating surface (5), and
wherein, in the second position of the carriage-shaped or carriage-like actuating element (7), the carriage-shaped or carriage-like actuating element (7) is positioned at least partially or regionally within a detection range of the sensor apparatus (6).

3. The actuating apparatus (1) according to claim 2,
wherein a spring is associated with the carriage-shaped or carriage-like actuating element (7) for biasing the carriage-shaped or carriage-like actuating element (7) into its first position.

4. The actuating apparatus (1) according to claim 3,
wherein the spring is configured as a spring-elastic region (11) of the carriage-shaped or carriage-like actuating element (7).

5. The actuating apparatus (1) according to claim 4,
wherein the spring-elastic region (11) of the carriage-shaped or carriage-like actuating element (7) is formed at or in a first end region of the carriage-shaped or carriage-like actuating element (7), and
wherein an end region of the spring-elastic region (11) facing away from a main body (12) of the carriage-shaped or carriage-like actuating element (7) is releasably connected to a housing structure (4) of the handle part (3).

6. The actuating apparatus (1) according to claim 5,
wherein, in the second position of the carriage-shaped or carriage-like actuating element (7), a second end region of the carriage-shaped or carriage-like actuating element (7) opposite the first end region of the carriage-shaped or carriage-like actuating element (7) is located at least partially or regionally within the detection range of the sensor apparatus (6).

7. The actuating apparatus (1) according to claim 1,
wherein the transfer mechanism comprises a straight-line guide (14) formed at least partially or regionally in the handle part (3), wherein the carriage-shaped or carriage-like actuating element (7) can be moved in a translational manner.

8. The actuating apparatus (1) according to claim 1,
wherein the transfer mechanism comprises at least one stop (15) associated with the carriage-shaped or carriage-like actuating element (7) for limiting a translational movement that can be performed by the carriage-shaped or carriage-like actuating element (7).

9. The actuating apparatus (1) according to claim 8,
wherein the at least one stop (15) associated with the carriage-shaped or carriage-like actuating element (7) is integrally formed with a housing structure (4) of the handle part (3).

10. The actuating apparatus (1) according to claim 1,
wherein the transfer mechanism is configured to convert a compressive force applied to the actuating surface (5) into a translational movement of the carriage-shaped or carriage-like actuating element (7), via an inclined plane.

11. The actuating apparatus (1) according to claim 10,
wherein at least one wedge-shaped or ramp-shaped protrusion (16) is formed on a rear side of the actuating surface (5), being received at least partially or regionally in a receiving region (17) that is configured in a main body (12) of the carriage-shaped or carriage-like actuating element (7),
wherein the at least one wedge-shaped or ramp-shaped protrusion (16) and/or the receiving region (17) is configured such that, when a compressive force is applied to the actuating surface (5) of the handle part (3), the wedge-shaped or ramp-shaped protrusion (16) is moved further into the receiving region (17), as a result of which the carriage-shaped or carriage-like actuating element (7) is pushed in a direction of the translational movement that can be performed by the carriage-shaped or carriage-like actuating element (7).

12. The actuating apparatus (1) according to claim 2,
wherein the transfer mechanism is configured to move the carriage-shaped or carriage-like actuating element (7) in a translational manner relative to the actuating surface (5) only when a critical compressive force is exceeded, a compressive force that is predefined or definable and is applied to the actuating surface (5) of the handle part (3).

13. The actuating apparatus (1) according to claim 12,
wherein the transfer mechanism comprises a pressure point that is perceptible acoustically and/or in a tactile manner via the actuating surface (5) upon exceeding the critical compressive force applied to the actuating surface (5) of the handle part (3).

14. The actuating apparatus (1) according to claim 13,
wherein, in order to implement the pressure point that is perceptible acoustically and/or in a tactile manner via the actuating surface (5), the transfer mechanism comprises a snap-action spring, being configured as a snap-action frog.

15. The actuating apparatus (1) according to claim 14,
wherein the snap-action spring is configured as a contact-transmitting component with respect to the sensor apparatus (6) as a snap dome.

16. The actuating apparatus (1) according to claim 12,
wherein the carriage-shaped or carriage-like actuating element (7) comprises at least one spring-elastically mounted region (18), which, in the resting position of the carriage-shaped or carriage-like actuating element (7), strikes against a protrusion (19) connected to a housing structure (4) of the handle part (3), and
wherein, when the critical compressive force applied to the actuating surface (5) of the handle part (3) is exceeded, an engagement between the at least one spring-elastically mounted region (18) of the carriage-shaped or carriage-like actuating element (7) and the protrusion (19) of the housing structure (4) of the handle part (3) is lifted.

17. The actuating apparatus (1) according to claim 16,
wherein the at least one spring-elastically mounted region (18) comprises an arm region extending in the direction of the translational movement that can be performed by the carriage-shaped or carriage-like actuating element (7),
wherein, at a first end region of the arm region, a wedge-shaped stop surface (20), an incline, is formed, which in the first position of the carriage-shaped or carriage-like actuating element (7), strikes against the protrusion (19) of the housing structure (4) of the handle part (3), and
wherein a second end region opposite the first end region of the arm region is connected to a main body (12) of the carriage-shaped or carriage-like actuating element (7).

18. The actuating apparatus (1) according to claim 1,
wherein the sensor apparatus (6) is configured as a microswitch.

19. The actuating apparatus (1) according to claim 1,
wherein the actuating apparatus (1) further comprises a mounting structure (2), which, when the actuating apparatus (1) is used as intended, is at least partially or regionally fastened to the vehicle door, or is received within the vehicle door, and
wherein a housing structure (4) of the handle part (3) is connected to the mounting structure (2) and integrally formed with the mounting structure (2).

20. The actuating apparatus (1) according to claim 1,
wherein, when the actuating apparatus (1) is used as intended, the handle part (3) protrudes at least partially or regionally from the vehicle door or a vehicle body from a vehicle outer skin, in such a way that the handle part (3) can be manually grasped at least partially or regionally, wherein the actuating surface (5) of the handle part (3) is formed on or in a surface of the handle part (3) facing the vehicle door or the vehicle body.
